(19) United States
(12) Patent Application Publication
(10) Pub. No.: US 2022/0140826 A1
(43) Pub. Date: May 5, 2022

(54) TEMPERATURE CONTROL FOR POWER DEVICES

(71) Applicant: TEXAS INSTRUMENTS INCORPORATED, Dallas, TX (US)

(72) Inventors: Orlando Lazaro, Cary, NC (US); Timothy Merkin, Princeton, TX (US); John Russell Broze, Dallas, TX (US); Matthew Xiong, Plano, TX (US); Yogesh Kumar Ramadass, San Jose, CA (US); Ujwal Radhakrishna, San Jose, CA (US)

(21) Appl. No.: 17/490,660

(22) Filed: Sep. 30, 2021

Related U.S. Application Data
(60) Provisional application No. 63/107,186, filed on Oct. 29, 2020.

(51) Int. Cl. H03K 17/14; H03K 17/0812

(52) U.S. Cl. CPC H03K 17/145; H03K 2017/0806; H03K 17/08122

(57) ABSTRACT

In a described example, a circuit includes a power device having voltage inputs and a command input. A sensing circuit has a sensor input and a sensor output, in which the sensor input is coupled to the power device. A control circuit has a control input and a control output, in which the control input coupled to the sensor output. A driver circuit has a driver input and a driver output. The driver input is coupled to the control output, and the driver output is coupled to the command input of the power device.

### CROSS-REFERENCE TO RELATED APPLICATIONS

This application claims priority to U.S. Provisional patent application No. 63/107,186, filed Oct. 29, 2020, which is incorporated herein by reference in its entirety.

### TECHNICAL FIELD

This description relates to controlling temperature of power devices.

### BACKGROUND

Avalanche breakdown relates to a phenomenon that can occur in both insulating and semiconducting materials when an electric field across a p-n junction has energy sufficient to create free charge carriers that collide with bound electrons to create more free charge carriers. The increase in free charge carriers results in a significant increase in current through a p-n junction. During overvoltage stress conditions, a power device may experience excessive power dissipation responsive to avalanche breakdown. The increased power dissipation induces junction temperature rise of the power device and the package it is contained in. In some circumstances, the temperature rise can cause damage to the device (e.g., delamination of the package).

### SUMMARY

In a described example, a circuit includes a power device having voltage inputs and a command input. A sensing circuit has a sensor input and a sensor output, in which the sensor input is coupled to the power device. A control circuit has a control input and a control output, in which the control input coupled to the sensor output. A driver circuit has a driver input and a driver output. The driver input is coupled to the control output, and the driver output is coupled to the command input of the power device.

In another described example, a circuit includes a power device having voltage input terminals and a command input. The power device is configured to conduct current between the voltage inputs responsive to a control input signal. A thermal sensor is configured to sense temperature of the power device and provide a sensor signal responsive to the sensed temperature. A driver circuit configured to provide a driver signal to the command input of the power device to turn on the power device responsive to the sensor signal and reduce the temperature of the power device.

In a further described example, a system includes an integrated circuit (IC) having voltage input terminals. The IC includes a power device having input terminals and a command input, the input terminals of the power device being coupled to the voltage input terminals of the IC. The IC also includes a sensor coupled to the power device, the sensor configured to provide a sensor signal responsive to detecting an overstress event of the power device. The IC also includes a driver circuit coupled to the command input of the power device and configured to drive the power device responsive to the sensor signal. A test system includes a voltage source coupled to the voltage input terminals and is configured to provide a test voltage to cause the overstress event of the power device.

### BRIEF DESCRIPTION OF THE DRAWINGS

FIG. 1 is a block diagram showing an example circuit configured to control temperature of a power device.

FIG. 2 depicts an example circuit configured to control temperature of a power device.

FIG. 3 depicts an example of a temperature control circuit.

FIG. 4 depicts another example circuit configured to control temperature of a power device.

FIG. 5 depicts an example system that includes a power device and circuit configured to control temperature of the power device during a high potential test.

FIG. 6 is a graph showing plots of signals in the system of FIG. 5.

### DETAILED DESCRIPTION

Example embodiments relate to circuitry and methods to control the temperature of power devices. As used herein, the term power device refers to a semiconductor device, which can be implemented in an integrated circuit (IC) chip and used as switch or rectifier or other type of power electronic device. Examples of power devices include metal-oxide semiconductor field-effect transistors (MOSFETs), insulated-gate bipolar transistors (IGBTs), bipolar junction transistors (BJTs), laterally-diffused metal-oxide semiconductor (LDMOS) FETs, and the like.

In an example, a circuit includes a power device having voltage inputs and a control input. A sensing circuit has a sensor input and a sensor output, in which the sensor input is coupled to the power device. A control circuit has a control input and a control output, in which the control input is coupled to the sensor output. The control circuit can be implemented as part of the sensing circuit or as a separate circuit. A driver circuit has a driver input and a driver output. The driver input is coupled to the control input, and the driver output is coupled to the control input of the power device. For example, the sensing circuit is configured to sense an overstress condition of the power device, such as by sensing temperature, voltage or current of the power device. The control circuit is configured to modulate a control signal at the driver input responsive to the sensed overstress condition. As a result, the power device is operated during the sensed overstress condition responsive to the control signal to reduce temperature of the power device accordingly.

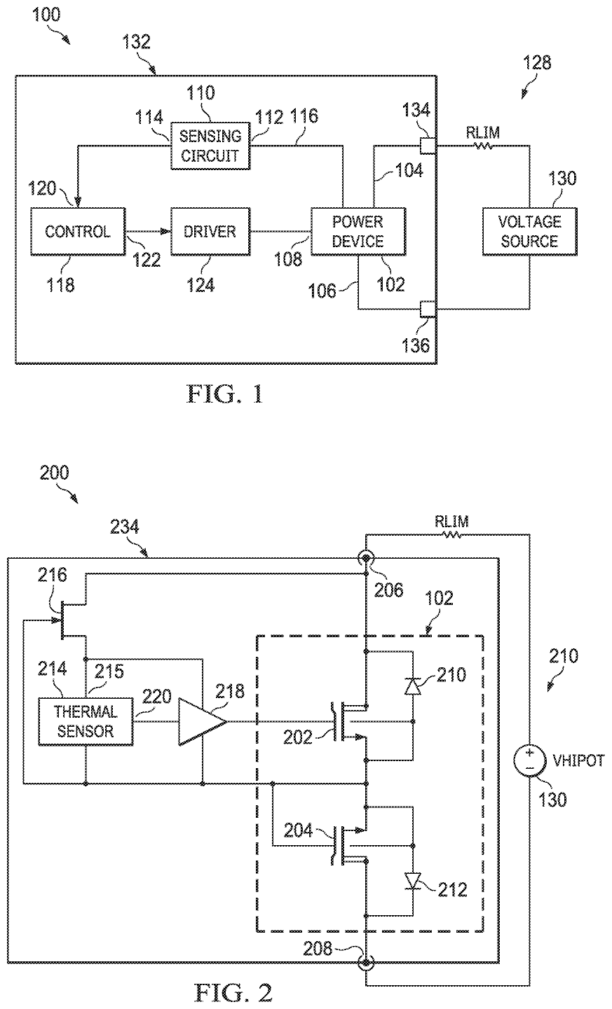

FIG. 1 is a block diagram showing an example circuit 100. The circuit 100 includes a power device 102 having voltage inputs 104 and 106 and a command input 108. For example, the power device includes one or more transistors coupled between the inputs 104 and 106. The power device 102 thus can be implemented as metal oxide semiconductor field effect transistors (MOSFETs), bipolar junction transistors (BJTs), junction field effect transistors (JFETs), insulated-gate bipolar transistors (IGBTs) or other types of transistors. In an example, the power device is implemented as a power MOSFET including a body diode coupled between the source and drain of the MOSFET, which are coupled to the inputs 104 and 106. When a reverse bias is applied between drain and source, an electric field is set up across the P-N junction of the body diode. When the applied voltage increases beyond a breakdown voltage, a critical field is reached where the junction can no longer support the applied voltage. The increased voltage results in avalanche breakdown in which reverse current flows through the body diode.

The circuit also includes a sensing circuit 110 having a sensor input 112 and a sensor output 114. The sensor input 112 is coupled to the power device 102 is coupled to the power device 102. For example, the coupling, schematically shown at 116, can include a conductive coupling, such as electrically conductive and/or thermally conductive connections. The sensing circuit 110 is configured to detect an avalanche condition of the power device 102 and provide a sensor signal representative of the sensed avalanche condition. As used herein, the term avalanche condition refers to an electrical breakdown of insulating region of the power device 102 (e.g., a p-n junction of a semiconductor power device) responsive to an applied electric field. For example, application of a sufficiently high voltage and/or current to the inputs 104 and 106 of the power device while the power device is turned off (e.g., not activated), such as during a high-potential (HIPOT) test, can create an electric field across an insulating region of the power device sufficient to trigger electrical breakdown. Electrical current thus can flow through the power device responsive to the electrical breakdown. The sensing circuit can sense temperature and/or an electrical characteristic of the power device to detect the overstress (e.g., avalanche) condition.

In an example, the sensing circuit 110 is a thermal sensor arranged adjacent the power device 102 and configured to measure the temperature of the power device and provide the sensor signal representative of the temperature. In another example, the sensing circuit 110 is configured to measure an electrical characteristic (e.g., voltage, current, power) of the power device 102, such as a voltage and/or current of the power device, and provide the sensor signal responsive to the measured electrical characteristic. In an example, circuit 100 is implemented as an IC including the power device 102 and the sensing circuit 110 on a common substrate (e.g., die) within IC packaging material.

The circuit 100 also includes a control circuit 118 having a control input 120 and a control output 122. The control input 120 is coupled to the sensor output 114. The control output 122 is coupled to a driver input of a driver circuit 124. The control circuit 118 is configured to provide a control signal to the driver circuit 124 responsive to the sensor signal. For example, the control circuit 118 is configured to compare the sensor signal to a threshold, and provide the control signal as a pulse or series of pulses responsive to the sensor signal indicating an avalanche condition for the power device. In the example of FIG. 1, the control circuit 118 and the sensing circuit 110 are shown as separate circuits. In another example, the sensing circuit 110 and the control circuit 118 can be combined in circuitry configured to perform respective sensing and control functions.

The driver circuit 124 has a driver output coupled to the command input 108 of the power device. The driver circuit 124 is configured to supply a drive signal to the command input responsive to the control signal at 122. The power device is configured to activate (e.g., turn on) responsive to the drive signal to reduce power dissipated by the power device during the avalanche condition.

For example, the sensing circuit 110, control circuit 118 and driver circuit 124 are configured as a “turn-on” control loop to regulate operation of the power device 102 during avalanche conditions. In an example, the control circuit 118 is configured to provide the control signals as pulses having a duty cycle responsive to the sensor signal. The duty cycle of the control signal can be fixed or it can vary over time. For example, the duty cycle can be set responsive to temperature variations of the power device. The control circuit 118 can be configured to repeatedly activate the power device to conduct current when a first temperature threshold and then deactivate the power device when a lower temperature threshold is reached, such as to provide hysteretic control responsive to device temperature. Thus, by activating (e.g., turning on) the power device 102 responsive to detecting an avalanche condition, less power is dissipated by the power device. The reduced power dissipation further enables a decrease in temperature of the power device.

As a further example, a test system 128 is shown coupled to the circuit 100. The test system 128 includes a voltage source 130 coupled in series with a limit resistor RLIM between voltage inputs 104 and 106 of the power device. In an example, the circuit is implemented as an IC 132 and the voltage inputs 104 and 106 of the power device are coupled to terminals 134 and 136 of the IC 132. Thus, RLIM and the voltage source can be coupled to terminals 134 and 136, as shown in FIG. 1, such as for testing of circuitry in the IC. For example, the voltage source is configured to perform a HIPOT by applying a high-stress voltage that can be up to about five times the normal blocking requirement of the power device. Such high-stress voltages tend to increase power dissipation of the power device, which can also increase the die temperature. For example, the increase in die temperature can damage packaging of the IC, such as causing delamination. Existing approaches to reduce power dissipation include increasing the size of RLIM or adding clamping circuitry across the terminals 134 and 136. Both of which can significantly increase the cost of the circuit 100. The approach used herein to activate the power device 102 responsive to detecting an overstress event of the power device, such as avalanche breakdown, enables the size (and cost) of RLIM to be decreased compared to existing approaches. The approach herein further does not require additional (expensive) clamping circuitry.

FIG. 2 depicts an example circuit 200 configured to control temperature of a power device 102. The circuit 200 is an example embodiment of the circuit 100 shown in FIG. 1. Accordingly, the description of FIG. 2 also refers to FIG. 1. In the example of FIG. 2, the power device 102 includes a pair of power FETs 202 and 204 coupled in series between voltage input terminals 206 and 208. In particular, the FETs 202 and 204 are shown in a common source configuration, in which the sources of each FET are coupled together. The common-source configuration, which is useful for providing bi-directional voltage blocking. The drain of each FET 202 and 204 is coupled to a respective input terminal 206 and 208. Each of the FETs 202 and 204 also includes a body diode 210 and 212 coupled between respective sources and drains of the FETs. The body diodes 210 and 212 have semiconductor junctions configured to block reverse current flow from the drain to the source of the respective FETs 202 and 204.

The circuit 200 also includes a thermal sensor 214 coupled to the power device 102. In the example of FIG. 2, the thermal sensor 214 has a voltage input 215 coupled to a transistor 216. For example, the transistor 216 is a JFET coupled between terminal 206 and the input 215 of the thermal sensor 214, in which the source of the JFET is coupled to the voltage input 215. The voltage input 215 is also coupled to a voltage input of a driver 218. The JFET 216 is configured to supply an input voltage to operate the thermal sensor 214 and the driver 218, such as responsive to a voltage potential is applied across terminals 206 and 208. For example, when the gate of the JFET is grounded, the JFET is configured (e.g., operating in pinch-off) to provide a low-voltage supply (e.g., about 5-20 V) at its source to run the control circuitry. When the drain of the JFET is low, the JFET is configured (e.g., operating in the triode region) to behave like a switch to turn off the control circuitry. An output 220 of the thermal sensor 214 is coupled to an input of the driver 218. The driver 218 has an output coupled to the gate of FET 202. The gate of FET 204 is coupled to the common source terminals of the FETs 202 and 204. The thermal sensor 214 and driver 218 have ground terminals also coupled to the common source terminals of the FETs 202 and 204.

In other examples, different numbers and configurations of one or more power devices 102 can be used than as shown in FIG. 2. In the example of FIG. 2 as well as such other examples, the circuit 200 can include one or more instances of the thermal sensor 214 and driver 218 (or other circuitry) configured to drive the respective power devices 102 responsive to detecting an avalanche condition. Similarly, separate sensing and control circuitry, such as described herein, can be implemented to control the power device 204 in response to detecting an avalanche condition of the power device 204.

The thermal sensor 214 is configured to provide a sensor signal at the output 220 responsive to the temperature of the power device. The driver 218 is configured to control the power device 102 responsive to the sensor signal. In an example, the thermal sensor 214 is implemented as a “shut-on” sensor configured to turn on the power device 102 (through the driver 218) responsive to the sensed temperature exceeding a temperature threshold. The temperature threshold can be configurable. In a further example, the thermal sensor 214 is configured to implement hysteretic control in which the thermal sensor provides the sensor signal at a logic high to turn on the FET 202 responsive to the temperature exceeding a first threshold and to provide the sensor signal at a logic low to turn off the FET 202 responsive to the temperature falling below a second threshold. As a result, the FET 202 is turned on and off (e.g., toggled) responsive to the duty cycle of the sensor output signal, and the duty cycle of the sensor signal is responsive to temperature of the power device 102.

As a further example, terminals 206 and 208 are adapted to be coupled to a test system 210. For example, similar to FIG. 1, the test system 210 includes resistor RLIM and voltage source 130 coupled in series between terminals 206 and 208. The voltage source 130 is configured to provide an output voltage, shown as VHIPOT, such as for testing the circuit 200. Thus, responsive to applying the voltage VHIPOT across terminals 206 and 208, avalanche breakdown can occur across the PN junction of the body diode 210 of FET 202 to provide for current flow through the channel of the FET 202. The diode 212 can be forward biased to conduct current through the FET 204. Power will dissipate responsive to the avalanche condition, which results in an increase in temperature of the power device 102. As described above, the thermal sensor 214 is configured to provide the sensor signal to control the FET 202 and thereby regulate the temperature of the power device responsive to the sensed temperature.

In an example, the circuit 200 is implemented as an IC 234 that includes the power device 102, thermal sensor 214, driver 218 and transistor 216 implemented on a common substrate (e.g., semiconductor die). In the example IC 234, the thermal sensor can measure the temperature of the die at a location where the thermal sensor is implemented, which depends on the temperature of the power device 102.

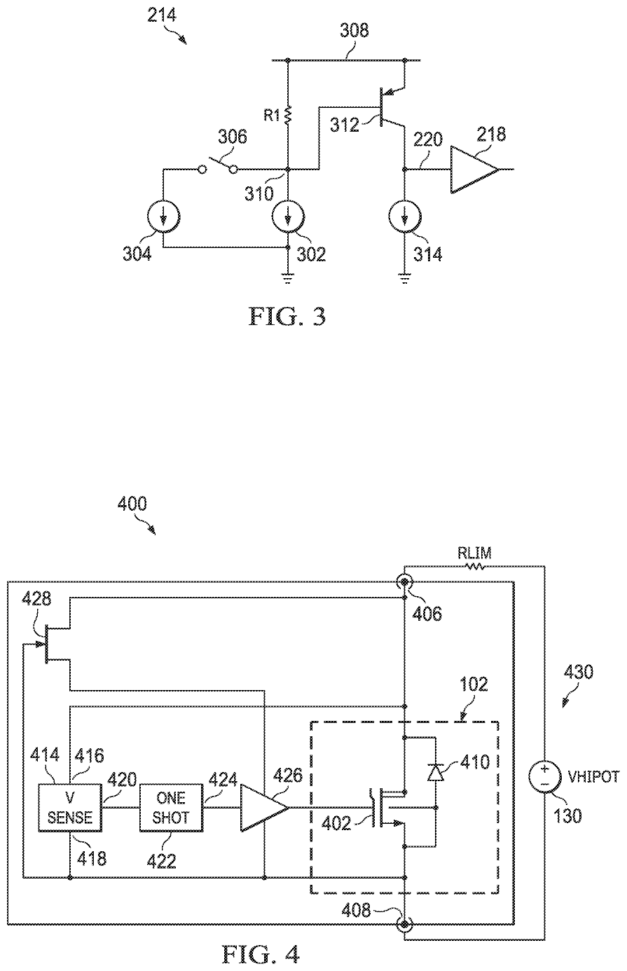

FIG. 3 shows an example of a thermal sensor 214, which can be used in the example of FIG. 2. Accordingly, the description of FIG. 3 also refers to FIG. 2. The thermal sensor 214 includes current sources 302 and 304. A switch (e.g., a FET) 306 is coupled in series with current source 304 in parallel with the current source 302. In an example, current source 302 is a proportional to absolute temperature (PTAT) current source configured to provide current that is responsive (e.g., proportional) to temperature of the substrate on which the current source is formed. The other current source 304 can also be a PTAT current source. A resistor R1 is coupled between a voltage terminal 308 the juncture (e.g., terminal) 310 to which the current source 302 and switch 306 are coupled. The terminal 310 is also coupled to the base of a transistor 312. The emitter of transistor 312 is coupled to terminal 308, and a collector of transistor is coupled to ground through another current source 314, which is configured to sink current from the collector of transistor 312. The voltage difference between voltages at 308 and 310 (e.g., the emitter-base voltage of 312) increases responsive to an increase in temperature to control the transistor 312 due to the PTAT nature of current sources 304 and 302. The transistor 312 is activated to couple the output 220 of the thermal sensor to the voltage terminal responsive to the increase in temperature, which is provided to the input of driver 218. In an example, the output of the sensor 220 is used to control the state of switch 306, so that when 220 is logic high, the switch 306 is enabled and exhibits hysteresis responsive to temperature. As a result, the sensor output at 220 can have a duty cycle responsive to the sensed temperature (e.g., due to hysteresis of enabling or disabling the PTAT current source 302 using switch 306).

FIG. 4 depicts an example circuit 400 configured to control temperature of a power device 102. The circuit 400 is another example embodiment of the circuit 100 shown in FIG. 1. Accordingly, the description of FIG. 4 also refers to FIG. 1. In the example of FIG. 4, the power device 102 includes a FET 402 coupled between voltage input terminals 406 and 408. Similar to as described with respect to FIG. 2, the FET 402 also includes a body diode 410 coupled between respective sources and drains of the FETs. The body diode 410 has a semiconductor junction configured to block reverse current flow from the drain to the source of the respective FET 402.

The circuit 400 also includes a sensor to detect an overstress condition. In the example of FIG. 4, the sensor is implemented as a voltage sensor 414 having first and second inputs 416 and 418 and a sensor output 420. The first input is coupled to the drain of FET 402 and the second input coupled to the source of the FET 402. The sensor output 420 is coupled to an input of a one-shot circuit 422. The one-shot circuit 422 has an output 424 coupled to an input of a driver circuit 426. The driver circuit 426 has an output coupled to the control input of the power device 102 (e.g., the gate of FET 402).

The voltage sensor 414 is configured to measure a voltage across the FET 402, which also provides a measure of the voltage across body diode 410. The voltage sensor 414 provides a sensor output signal at the output 420 representative of the sensed voltage across the FET 402. For example, the voltage sensor 414 is implemented as a voltage divider circuit (e.g., a resistive voltage divider) configured to provide the voltage representative of the drain voltage of the FET 402. A comparator can compare the voltage divider output with a reference so the comparator provides a first output (e.g., logic high) when the measured voltage exceeds the reference and a second output (e.g., logic low) when the measured voltage does not exceed the reference. In other examples, different configurations of circuitry can be used to implement the voltage sensor 414. The one-shot circuit 422 is configured to control the driver responsive to the sensor output signal at 420, such as by providing a trigger pulse signal having a duration. The duration of the trigger pulse signal at 424 can be fixed, and can be configurable. The driver circuit 426 is configured to drive the power device responsive to the trigger pulse at 424. The driver circuit 426 also has a supply input coupled to a transistor (e.g., JFET) 428. The JFET thus is configured to provide a supply voltage to the driver circuit 426 and the driver circuit provides the drive signal to the power device (with a magnitude) responsive to the voltage drop across the transistor 428.

As an example, terminals 406 and 408 are adapted to be coupled to a test system 430. Similar to FIG. 2, the test system 430 can include resistor RLIM and voltage source 130. The voltage source 130 is configured to provide an output voltage VHIPOT, such as for testing the circuit 400. For example, when the FET 402 is turned off and not undergoing an avalanche breakdown, the power dissipated in the FET 402 is not of thermal concern (e.g., at about sub mW levels). If the voltage (e.g., VHIPOT) applied across 406 and 408 exceeds the breakdown voltage of the FET 402, an avalanche condition occurs, in which the body diode 410 is reverse biased to conduct current from the drain to the source. During the avalanche condition, the voltage sensor 414 measures the voltage across FET 402, which approximates the voltage at 406 (e.g., VHIPOT less the voltage drop across RLIM). The voltage sensor 414 can provide the sensor signal to drive the input of the one-shot circuit responsive to the detected voltage. The one-shot circuit is configured to supply a pulse having a duration to trigger driver circuit 426 to drive the gate of the FET 402 (e.g., with a gate-to-source voltage to FET 402 sufficient to turn on the FET) and turn on the FET to conduct current through its channel for a time interval commensurate to the duration of the one-shot pulse. As described herein, when the FET is turned on, the FET dissipates less heat and cools down. After the duration, the driver removes the voltage from the gate of the FET 402 and the FET turns off. Assuming the VHIPOT is still being provided, the FET will experience avalanche breakdown and dissipate heat. Responsive to the avalanche breakdown, the voltage sensor 414 triggers the one-shot circuit 422 to turn on the FET for a duration. This process can repeat during the application of VHIPOT to regulate the temperature of the power device and the circuit 400 (e.g., implemented as an IC) more generally, as described herein.

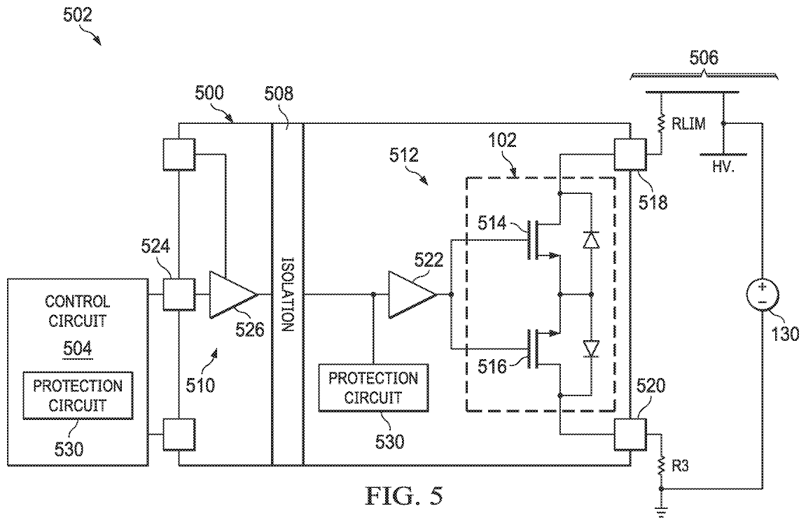

FIG. 5 depicts an example of system 500 that includes an IC 500, a control circuit 504 and a test system 506. In the example of FIG. 5, the IC 500 includes an isolation barrier 508 configured to electrically isolate one set of circuitry 510 from another set of circuitry 512. The circuitry 512 includes the power device 102 (shown in FIG. 1), which includes FETs 514 and 516 coupled between respective terminals 518 and 520. The test system 506 is coupled to the terminals 518 and 520. For example, the test system 506 includes a voltage source 130, resistor RLIM and another resistor R3 (e.g., RLIM>R3). A driver 522 is coupled to gates of the FETs 514 and 516 for driving the power device 102 in response to an input control signal.

For example, the control circuit 504 is configured to apply an enable input signal to an input terminal 524. An isolation driver 526 has an input coupled to the terminal 524. The isolation driver 526 is configured to provide an isolation control signal, which can pass through the isolation barrier (e.g., as an optical signal), which is converted back to an electrical signal that is as the input control signal to the driver 522 for controlling the power device 102.

The system 502 also includes a protection circuit 530. In an example, the protection circuit 530 is implemented as part of the circuitry 512 in the IC 500. In another example, the protection circuit 530 is implemented as part of the control circuit 504. In yet another example, the protection circuit 530 can be distributed among the circuitry 512 and the control circuit 504. The protection circuit 530 is configured to regulate the junction temperature of the power device 102 during over stress conditions, such as an avalanche condition. For example, the protection circuit 530 is configured to implement sensing and controls according to any of the examples described herein, including FIGS. 1, 2, 3 and 4. Because the protection circuit can effectively regulate the temperature of the power device 102, including each of the FETs 514 and 516, and the IC 500, a smaller resistor RLIM can be used in the system 502 compared to existing approaches.

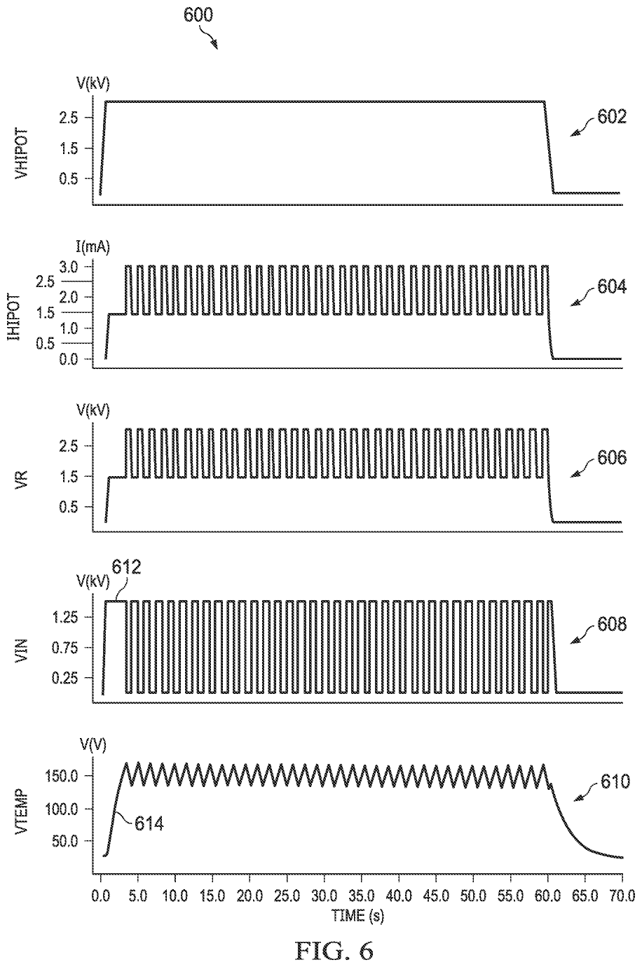

As a further example, FIG. 6 is a graph 600 showing plots 602, 604, 606, 608 and 610 of signals in the system of FIG. 5. The plot 602 shows an example of a test signal supplied by the voltage source 130 during a test interval (e.g., about 60 seconds). The plot 604 shows an example of current supplied by the test system at terminal 518 responsive to the test voltage and operation of the protection circuit 530, as described herein. Thus, during operation of the protection circuit 530, the current toggles with a duty cycle responsive to a duty cycle at which the FETs 514 and 516 are switched. The plot 606 shows the voltage drop across the resistor RLIM responsive to the test current (plot 604). As shown, in plot 606 an increased voltage drop occurs across RLIM responsive to turning on the FETs 514 and 516. The plot 608 shows the input voltage (VIN) across input terminals 518 and 520. A wider pulse 612 occurs initially responsive to the test signal VHIPOT because the protection circuit 530 has not yet triggered the FETs 514 and 516 to turn on. After the temperature has increased due to the test voltage VHIPOT, the protection circuit 530 is configured to control the FETs so that the input voltage 608 has a respective duty cycle as shown (e.g., after about 4 seconds). The plot 610 shows an example of a sensed temperature of the power device 102 (e.g., junction temperature of FET 514). The plot 610 thus shows the junction temperature increasing initially, at 614, and then the junction temperature being hysteretically regulated during the high stress condition (e.g., during the application of VHIPOT to the IC 500). If the protection circuit 530 did not implement temperature regulation, as described herein, the temperature could continue to increase, which could cause irreparable damage the IC 500 (e.g., delamination of the package). After the VHIPOT is removed, the power device 102 returns to normal operation and capable of blocking an input voltage at 518 that does not exceed the breakdown voltage of the FET 514.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A circuit comprising:
a power device having voltage inputs and a command input;
a sensing circuit having a sensor input and a sensor output, the sensor input coupled to the power device;
a control circuit having a control input and a control output, the control input coupled to the sensor output; and
a driver circuit having a driver input and a driver output, the driver input coupled to the control output, and the driver output coupled to the command input of the power device.

2. The circuit of claim 1, wherein the sensing circuit comprises a thermal sensor circuit coupled to the power device, the thermal sensor circuit having an output coupled to the driver input.

3. The circuit of claim 2, wherein the thermal sensor circuit comprises:
a proportional to absolute temperature (PTAT) current source coupled to the power device through a substrate, the PTAT current source configured to provide a bias signal to the control input of the control circuit responsive to a temperature of the substrate.

4. The circuit of claim 3, wherein the control circuit comprises a transistor having an input configured to receive the bias signal, the transistor having a voltage input coupled to a voltage supply terminal, the transistor having the control output coupled to the driver input.

5. The circuit of claim 3, wherein the PTAT current source is configured to provide a current that varies hysteretically responsive to the temperature of the substrate,
the control circuit is configured to regulate the temperature of the power device with a duty cycle responsive to the current of the PTAT current sensor.

6. The circuit of claim 1, wherein the sensing circuit comprises:
a voltage sensor having voltage inputs and an output, the voltage inputs of the voltage sensor coupled to the power device;
a one-shot circuit having an input and an output, the output of the voltage sensor coupled the input of the one-shot circuit, and the output of the one-shot circuit coupled to the driver input.

7. The circuit of claim 6, wherein the one-shot circuit is configured to modulate the driver input responsive to a voltage sensor signal at the output of the voltage sensor.

8. The circuit of claim 1, wherein the circuit is implemented as an integrated circuit, the integrated circuit comprising a substrate, the power device and the sensing circuit implemented on the substrate.

9. The circuit of claim 1, wherein the power device comprises:
a first field effect transistor (FET) having a gate source and drain, the drain of the first FET coupled to a first of the voltage inputs; and
a second FET having a gate, source and drain, and the source of the first FET coupled to the source of the second FET, and the drain of the second FET coupled to a second of the voltage inputs.

10. The circuit of claim 1, further comprising:
a resistor; and
a voltage source coupled in series with the resistor between the voltage inputs of the power device.

11. A circuit comprising:
a power device having voltage input terminals and a command input, the power device configured to conduct current between the voltage inputs responsive to a control input signal;
a thermal sensor configured to sense temperature of the power device and provide a sensor signal responsive to the sensed temperature; and
a driver circuit configured to provide a driver signal to the command input of the power device to turn on the power device responsive to the sensor signal and reduce the temperature of the power device.

12. The circuit of claim 11, wherein the power device comprises:
a field effect transistor (FET), the voltage input terminals being a drain and a source of the FET, the FET having a body diode between the source and the drain, the FET configured to conduct reverse current through the body diode responsive to a voltage potential between the drain and the source exceeding a breakdown voltage of the FET.

13. The circuit of claim 12, wherein the thermal sensor comprises:
a proportional to absolute temperature (PTAT) current source coupled to the power device, the PTAT current source configured to conduct current responsive to the temperature of the power device.

14. The circuit of claim 13, wherein the thermal sensor comprises a transistor, the transistor configured to control the driver circuit responsive to the bias signal.

15. The circuit of claim 14, wherein the PTAT current source is configured to provide the bias signal to vary hysteretically responsive to the temperature of the power device.

16. The circuit of claim 12, wherein the circuit is implemented as an integrated circuit comprising a substrate, the power device and the thermal sensor implemented on the substrate of the integrated circuit.

17. The circuit of claim 11, further comprising a test system configured to provide a test voltage to the voltage input terminals during a test interval, the test voltage exceeding a breakdown voltage of the power device.

18. The circuit of claim 17, wherein the thermal sensor is configured to provide the sensor signal with a duty cycle to control the power device to conduct current during the test interval responsive to the sensed temperature.

19. A system comprising:
an integrated circuit (IC) having voltage input terminals, the IC comprising:
a power device having input terminals and a command input, the input terminals of the power device coupled to the voltage input terminals of the IC;
a sensor coupled to the power device, the sensor configured to provide a sensor signal responsive to detecting an overstress event of the power device; and
a driver circuit coupled to the command input of the power device and configured to drive the power device responsive to the sensor signal; and
a test system comprising a voltage source coupled to the voltage input terminals configured to provide a test voltage to cause the overstress event of the power device.

20. The system of claim 19, wherein the driver circuit is configured to supply a drive signal to the command input of the power device, the drive signal having a duty cycle during the overstress event.

21. The system of claim 20, wherein the overstress event comprises at least one of a temperature or an overvoltage condition.
